(19) United States
(12) Patent Application Publication
(10) Pub. No.: US 2014/0233332 A1
(43) Pub. Date: Aug. 21, 2014

(54) SEMICONDUCTOR MEMORY SYSTEM

(71) Applicant: SK hynix Inc., Icheon-si (KR)

(72) Inventor: Byung Deuk JEON, Icheon-si (KR)

(21) Appl. No.: 13/941,777

(22) Filed: Jul. 15, 2013

(30) Foreign Application Priority Data
Feb. 20, 2013 (KR) 10-2013-0018041

(51) Int. Cl. G11C 11/402

(52) U.S. Cl. CPC G11C 11/402
USPC 365/191; 365/222

(57) ABSTRACT

A semiconductor memory system includes a semiconductor memory configured to provide an external circuit with a plurality of refresh characteristic information and perform an auto-refresh operation in response to a plurality of auto-refresh commands, and a memory controller configured to provide the semiconductor memory with the plurality of auto-refresh commands generated according to the plurality of refresh characteristic information.

### CROSS-REFERENCES TO RELATED APPLICATION

The present application claims priority under 35 U.S.C. §119(a) to Korean application number 10-2013-0018041 filed on Feb. 20, 2013, in the Korean Intellectual Property Office, which is incorporated herein by reference in its entirety.

### BACKGROUND

1. Technical Field

Various embodiments relate to a semiconductor circuit, and more particularly to a semiconductor memory system.

2. Related Art

FIG. 1 is a block diagram illustrating the configuration of a is semiconductor memory 1 according to a known art.

The semiconductor memory according to the known art has a plurality of channels operating independently.

That is, as illustrated in FIG. 1, the semiconductor memory 1 according to the known art includes a plurality of channels CHANNEL A to CHANNEL D.

Each of the plurality of channels CHANNEL A to CHANNEL D includes a peripheral circuit block.

In case of volatile semiconductor memory, the information eventually fades unless a refresh operation is performed. The semiconductor memory such as a dynamic random access memory (DRAM), therefore, should perform a refresh operation.

Accordingly, the semiconductor memory 1 according to the known art includes a refresh period signal generation block for determining a refresh operation period, that is, a self-refresh operation period.

The plurality of channels CHANNEL A to CHANNEL D share a refresh period signal SPERIOD generated in the refresh period signal generation block and perform the refresh operation in response to the refresh period signal SPERIOD.

Because the plurality of channels CHANNEL A to CHANNEL D share a refresh period signal SPERIOD, refresh periods of the plurality of channels CHANNEL A to CHANNEL D are determined based on a channel having the worst refresh characteristics determined in a test process (for example, a wafer test).

The channel having bad refresh characteristics needs to frequently perform a refresh operation, as compared with a channel having good refresh characteristics.

Therefore, according to the known art, since a channel having good refresh characteristics also performs a refresh operation with substantially the same period as that of a channel having bad refresh characteristics, unnecessary current consumption occurs, resulting in an increase in the entire current consumption of the semiconductor memory.

### SUMMARY

A semiconductor memory system capable of reducing current consumption is described herein.

In an embodiment of the present invention, a semiconductor memory system includes: a semiconductor memory configured to provide an exterior with a plurality of refresh characteristic information, and to perform an auto-refresh operation in response to a plurality of auto-refresh commands; and a memory controller configured to provide the semiconductor memory with the plurality of auto-refresh commands generated according to the plurality of refresh characteristic information.

The memory controller may be configured to independently set periods of the plurality of auto-refresh commands according to the plurality of refresh characteristic information.

In an embodiment of the present invention, a semiconductor memory system includes: a semiconductor memory configured to provide an exterior with a plurality of refresh characteristic information according to refresh characteristics of respective channels, to perform an auto-refresh operation for the respective channels in response to a plurality of auto-refresh commands, and to stop a self-refresh operation of a channel corresponding to a plurality of self-refresh stop commands; and a memory controller configured to provide the semiconductor memory with the plurality of auto-refresh commands and the plurality of self-refresh stop commands.

The memory controller may be configured to selectively activate the plurality of auto-refresh commands and the plurality of self-refresh stop commands according to the channel use information.

The semiconductor memory system of the present technology is able to reduce current consumption.

In an embodiment, a semiconductor memory system includes a self-refresh period control unit configured to generate a plurality of self-refresh period signals each having an independent period according to internal setting information; and a plurality of semiconductor memory cell regions configured to have different refresh characteristics from one another and each perform a self-refresh operation in response to one of the plurality of self-refresh period signals.

In an embodiment, a memory system includes a memory controller configured to generate a plurality of auto refresh commands according to a plurality of refresh characteristic information; and a semiconductor memory configured to provide an external circuit with the plurality of refresh characteristic information according to refresh characteristics of respective channels and perform an auto-refresh operation for the respective channels in response to the plurality of auto-refresh commands.

In an embodiment, an electronic device includes a semiconductor memory system communicatively coupled to a central processing unit; the semiconductor memory system comprising: a memory controller configured to generate a plurality of auto refresh commands according to a plurality of refresh characteristic information; and a semiconductor memory configured to provide an external circuit with the plurality of refresh characteristic information according to refresh characteristics of respective channels and perform an auto-refresh operation for the respective channels in response to the plurality of auto-refresh commands.

### BRIEF DESCRIPTION OF THE DRAWINGS

Features, aspects, and embodiments are described in conjunction with the attached drawings, in which:

FIG. 1 is a block diagram illustrating a configuration of a semiconductor memory 1 according to a known art;

FIG. 2 is a block diagram illustrating a configuration of a semiconductor memory system 100 according to an embodiment of the present invention;

FIG. 3 is a block diagram illustrating a configuration of a semiconductor memory 300 of FIG. 2 according to an embodiment of the present invention;

FIG. 4 is a circuit diagram of a self-refresh period control unit 800 of FIG. 3 according to an embodiment of the present invention; and

FIG. 5 is a waveform diagram of preliminary period signals Period<2:5> of FIG. 4 according to an embodiment of the present invention.

FIG. 6 is a block diagram illustrating a memory system according to an embodiment of the present invention.

FIG. 7 is a view illustrating an electronic device or a computing system according to an embodiment of the present invention.

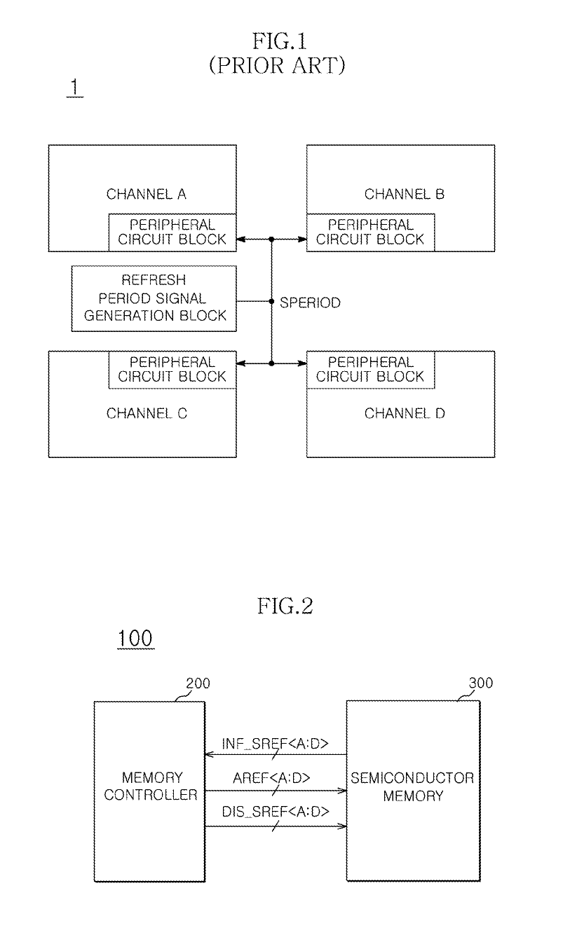

### DETAILED DESCRIPTION

Hereinafter, a semiconductor memory system according to the present invention will be described in detail with reference to the accompanying drawings through various embodiments of the present invention.

FIG. 2 is a block diagram illustrating the configuration of a semiconductor memory system 100 according to an embodiment of the present invention.

As illustrated in FIG. 2, the semiconductor memory system 100 according to an embodiment of the present invention includes a memory controller 200 and a semiconductor memory 300.

The semiconductor memory 300 is configured to perform a self-refresh operation with an independent period for each channel according to internal setting information.

Furthermore, the semiconductor memory 300 is configured to provide an external circuit with a plurality of refresh characteristic information INF_SREF<A:D> according to refresh characteristics of respective channels, perform an auto-refresh operation for the respective channels in response to a plurality of auto-refresh commands AREF<A:D>, and stop a self-refresh operation of channels corresponding to a plurality of self-refresh stop commands DIS_SREF<A:D>.

The memory controller 200 is configured to provide the semiconductor memory 300 with the plurality of auto-refresh commands AREF<A:D> and the plurality of self-refresh stop commands DIS_SREF<A:D>. The plurality of auto-refresh commands AREF<A:D> and the plurality of self-refresh stop commands DIS_SREF<A:D> may be generated according to the refresh characteristics of respective channels of the semiconductor memory 300. For example, plurality of auto-refresh commands AREF<A:D> and the plurality of self-refresh stop commands DIS_SREF<A:D> may be generated according to channel use information and the plurality of refresh characteristic information INF_SREF<A:D>.

The memory controller 200 may recognize channel use information as to which channels of the semiconductor memory 300 have been used. That is, the memory controller 200 may recognize which memory cells of the semiconductor memory 300 have been used to store data. For example, the memory controller 200 may recognize which memory cells of the semiconductor memory 300 do not have data therein according to the channel use information.

Each of the refresh characteristic information INF_SREF<A:D> may be set to have different value when each channel has different refresh characteristics. For example, a first information INF_SREF<A> of the refresh characteristic information INF_SREF<A:D> may be different from a second information INF_SREF<B> of the refresh characteristic information INF_SREF<A:D>. The refresh characteristics may be measured in a test process (for example, a wafer test) of each channel.

The refresh characteristic information INF_SREF<A:D> may be set up such that a refresh period of a channel having bad refresh characteristics is short.

Consequently, the memory controller 200 is able to recognize refresh characteristics of each channel according to the refresh characteristic information INF_SREF<A:D>.

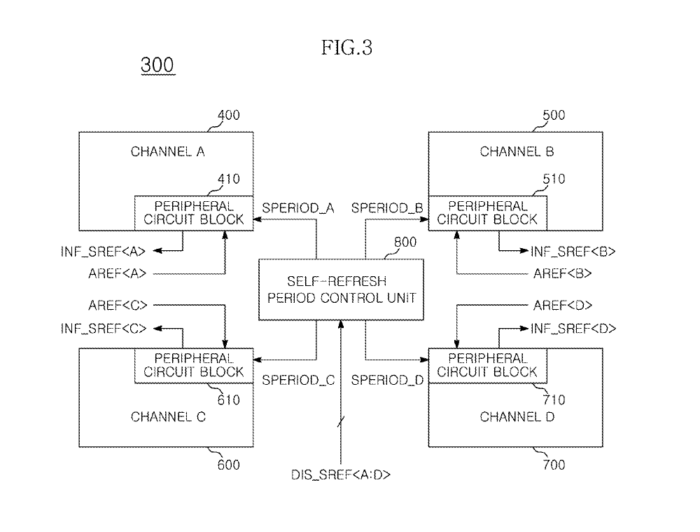

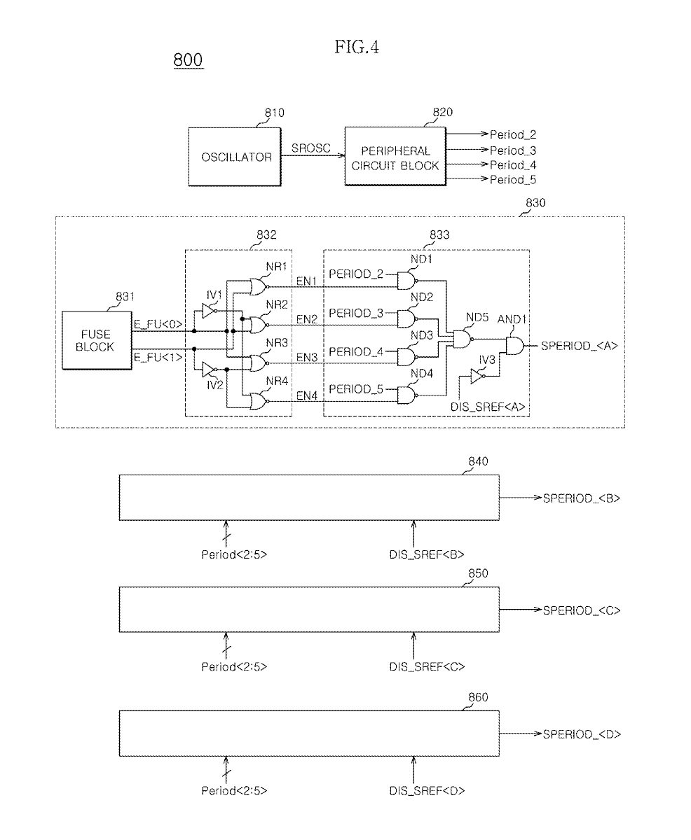

FIG. 3 is a block diagram illustrating a configuration of the semiconductor memory 300 of FIG. 2 according to an embodiment of the present invention.

As illustrated in FIG. 3, the semiconductor memory 300 of FIG. 2 includes a plurality of channels (hereinafter referred to as channel A, channel B, channel C and, channel D) 400, 500, 600, and 700, and a self-refresh period control unit 800.

The channel A 400 includes a peripheral circuit block 410. Although not illustrated in the drawing, the channel A 400 further includes a core block (not illustrated) having a memory area and an input/output circuit.

The peripheral circuit block 410 is configured to provide the memory controller 200 with the refresh characteristic information INF_SREF<A>, perform the auto-refresh operation in response to the auto-refresh command AREF<A>, and perform the self-refresh operation in response to a self-refresh period signal SPERIOD_<A>.

The channel B 500 includes a peripheral circuit block 510. Although not illustrated in the drawing, the channel B 500 further includes a core block (not illustrated) having a memory area and an input/output circuit.

The peripheral circuit block 510 is configured to provide the memory controller 200 with the refresh characteristic information INF_SREF<B>, perform the auto-refresh operation in response to the auto-refresh command AREF<B>, and perform the self-refresh operation in response to a self-refresh period signal SPERIOD_<B>.

The channel C 600 includes a peripheral circuit block 610. Although not illustrated in the drawing, the channel C 600 further includes a core block (not illustrated) having a memory area and an input/output circuit.

The peripheral circuit block 610 is configured to provide the memory controller 200 with the refresh characteristic information INF_SREF<C>, perform the auto-refresh operation in response to the auto-refresh command AREF<C>, and perform the self-refresh operation in response to a self-refresh period signal SPERIOD_<C>.

The channel D 700 includes a peripheral circuit block 710. Although not illustrated in the drawing, the channel D 700 further includes a core block (not illustrated) having a memory area and an input/output circuit.

The peripheral circuit block 710 is configured to provide the memory controller 200 with the refresh characteristic information INF_SREF<D>, perform the auto-refresh operation in response to the auto-refresh command AREF<D>, and perform the self-refresh operation in response to a self-refresh period signal SPERIOD_<D>.

The self-refresh period control unit 800 is configured to generate the plurality of self-refresh period signals SPERIOD_<A:D> having an independent period according to internal setting information, and selectively deactivate the plurality of self-refresh period signals SPERIOD_<A:D> in response to the plurality of self-refresh stop commands DIS_SREF<A:D>.

For example, the plurality of refresh characteristic information INF_SREF<A:D> may be used as the internal setting information.

The peripheral circuit blocks 410, 510, 610, and 710, according to an embodiment of the present invention, may provide the refresh characteristic information INF_SREF<A:D>. A storage area or a mode register, which may be provided outside the channel to store information about the semiconductor memory, may also provide the refresh characteristic information INF_SREF<A: D> according to an embodiment of the present invention.

FIG. 4 is a circuit diagram of the self-refresh period control unit 800 of FIG. 3 according to an embodiment of the present invention.

As illustrated in FIG. 4, according to an embodiment of the present invention, the self-refresh period control unit 800 of FIG. 3 includes an oscillator 810, a preliminary period signal generation section 820, and a plurality of period signal generation sections 830, 840, 850, and 860.

The oscillator 810 is configured to generate an oscillation signal SROSC.

The preliminary period signal generation section 820 is configured to generate a plurality of preliminary period signals PERIOD_{—}<2:5> in response to the oscillation signal SROSC.

The plurality of period signal generation sections 830, 840, 850, and 860 are configured to select one of the plurality of preliminary period signals PERIOD_{—}<2:5> according to respective internal setting information, and output the self-refresh period signals SPERIOD_<A:D>, respectively.

The plurality of period signal generation sections 830, 840, 850, and 860 are configured to deactivate the self-refresh period signals SPERIOD_<A:D> in response to the self-refresh stop commands DIS_SREF<A:D>.

The period signal generation section 830 is configured to select one of the plurality of preliminary period signals PERIOD<2:5> according to the internal setting information, output the self-refresh period signal SPERIOD_<A>, and deactivate the self-refresh period signal SPERIOD_<A> in response to the self-refresh stop command DIS_SREF<A>.

The period signal generation section 840 is configured to select one of the plurality of preliminary period signals PERIOD<2:5> according to the internal setting information, output the self-refresh period signal SPERIOD_<B>, and deactivate the self-refresh period signal SPERIOD_<B> in response to the self-refresh stop command DIS_SREF<B>.

The period signal generation section 850 is configured to select one of the plurality of preliminary period signals PERIOD<2:5> is according to the internal setting information, output the self-refresh period signal SPERIOD_<C>, and deactivate the self-refresh period signal SPERIOD_<C> in response to the self-refresh stop command DIS_SREF<C>.

The period signal generation section 860 is configured to select one of the plurality of preliminary period signals PERIOD<2:5> according to the internal setting information, output the self-refresh period signal SPERIOD_<D>, and deactivate the self-refresh period signal SPERIOD_<D> in response to the self-refresh stop command DIS_SREF<D>.

The period signal generation section 830 includes a fuse block 831, a decoding block 832, and a selection part 833.

The fuse block 831 is configured to output fuse signals E_FU<0:1> as the internal setting information. The output fuse signals E_FU<0:1> may be determined according to fuse status.

The fuse block 831 may include an electrical fuse.

The internal setting information, for example, the fuse signals E_FU<0:1> may have substantially the same value as that of the refresh characteristic information INF_SREF<A>.

The decoding block 832 is configured to decode the fuse signals E_FU<0:1> and generate a plurality of enable signals EN<1:4>.

The decoding block 832 includes a plurality of inverters IV1 and IV2 and a plurality of NOR gates NR1 to NR4.

The selection part 833 is configured to select one of the plurality of preliminary period signals PERIOD<2:5> according to the plurality of enable signals EN<1:4>, output the self-refresh period signal SPERIOD_<A>, and deactivate the self-refresh period signal SPERIOD_<A> in response to the self-refresh stop command DIS_SREF<A>.

In an embodiment of the present invention, the selection part 833 includes a plurality of NAND gates ND1 to ND4 each configured to perform a NAND operation on each of the plurality of enable signals EN<1:4> and each of the plurality of preliminary period signals PERIOD<2:5>. The selection part 833 also includes a NAND gate ND5 configured to perform a NAND operation on the outputs of the NAND gates ND1 to ND4, an inverter IV3 configured to invert the self-refresh stop command DIS_SREF<A>, and an AND gate AND1 configured to perform an AND operation on the output of the NAND gate ND5 and the output of the inverter IV3.

The other period signal generation sections 840, 850, and 860 may have substantially the same configuration as that of the period signal generation section 830.

FIG. 5 is a waveform diagram of the preliminary period signals Period<2:5> of FIG. 4 according to an embodiment of the present invention.

As illustrated in FIG. 5, the preliminary period signal generation section 820 may generate the plurality of preliminary period signals Period<2:5> by dividing the pulse frequency of the oscillation signal SROSC at different division ratios.

A refresh control operation of the semiconductor memory system 100 configured as above will be described as follows.

The semiconductor memory 300 provides the memory controller 200 with the refresh characteristic information INF_SREF<A:D> at a specific point of time, for example, when the semiconductor memory 300 is connected to the memory controller 200, or when the semiconductor memory 300 in a system initialization process.

The memory controller 200 may also read the refresh characteristic information INF_SREF<A:D> in a process in which the memory controller 200 reads the characteristic information of the semiconductor memory 300.

The semiconductor memory 300 performs the self-refresh operation in response to the self-refresh period signals SPERIOD_<A:D> independently provided to the channels by the self-refresh period control unit 800.

The memory controller 200 determines refresh characteristics of each channel of the semiconductor memory 300 according to the refresh characteristic information INF_SREF<A:D>, and provides the semiconductor memory 300 with the auto-refresh commands AREF<A:D> having an independent period according to the refresh characteristics.

That is, the memory controller 200 adjusts an auto-refresh period to be long for a channel having excellent refresh characteristics, as compared with a channel having bad refresh characteristics, thereby generating the auto-refresh commands AREF<A:D>.

For example, it is assumed that the channel A to the channel C, between the plurality of channels channel A to channel D, have excellent refresh characteristics and the channel D has relatively bad refresh characteristics.

The memory controller 200 provides the auto-refresh command AREF<D> at a short period as compared with the other auto-refresh commands AREF<A:C>.

Consequently, the semiconductor memory 300 is able to perform an auto-refresh operation for the channel A to the channel C a relatively small number of times as compared with the channel D.

Furthermore, the memory controller 200 recognizes whether memory cells of the channels of the semiconductor memory 300 are used to store data, that is, channel use information of a channel.

Consequently, the memory controller 200 is able to selectively activate the auto-refresh commands AREF<A:D> in consideration of the channel use information, thereby providing the activated auto-refresh command to the semiconductor memory 300.

For example, it is assumed that the channel A and the channel B, between the plurality of channels channel A to channel D, are in a state in which data has been recorded in memory cells thereof, and the channel C and the channel D are in a state in which no data has been recorded in memory cells thereof.

That is, the auto-refresh operation is not necessary for the channel C and the channel D.

The memory controller 200 may activate the auto-refresh commands AREF<A:B> and provide the activated auto-refresh commands AREF<A:B> to the semiconductor memory 300. The memory controller 200 may not activate the other auto-refresh commands AREF<C:D>.

Consequently, the semiconductor memory 300 may not perform the auto-refresh operation for the channel C and the channel D.

Furthermore, the memory controller 200 is able to selectively activate and output the self-refresh stop commands DIS_SREF<A:D> according to the channel use information.

For example, it is assumed that the channel A and the channel B, between the plurality of channels channel A to channel D, are in a state in which data has been recorded in memory cells thereof, and the channel C and the channel D are in a state in which no data has been recorded in memory cells thereof.

That is, the self-refresh operation is not necessary for the channel C and the channel D.

The memory controller 200 may activate the self-refresh stop commands DIS_SREF<C:D> and provide the activated self-refresh stop commands DIS_SREF<C:D> to the semiconductor memory 300.

The semiconductor memory 300 deactivates the self-refresh period signals SPERIOD_<C:D> corresponding to the channel C and the channel D, thereby stopping the self-refresh operation for the channel C and the channel D.

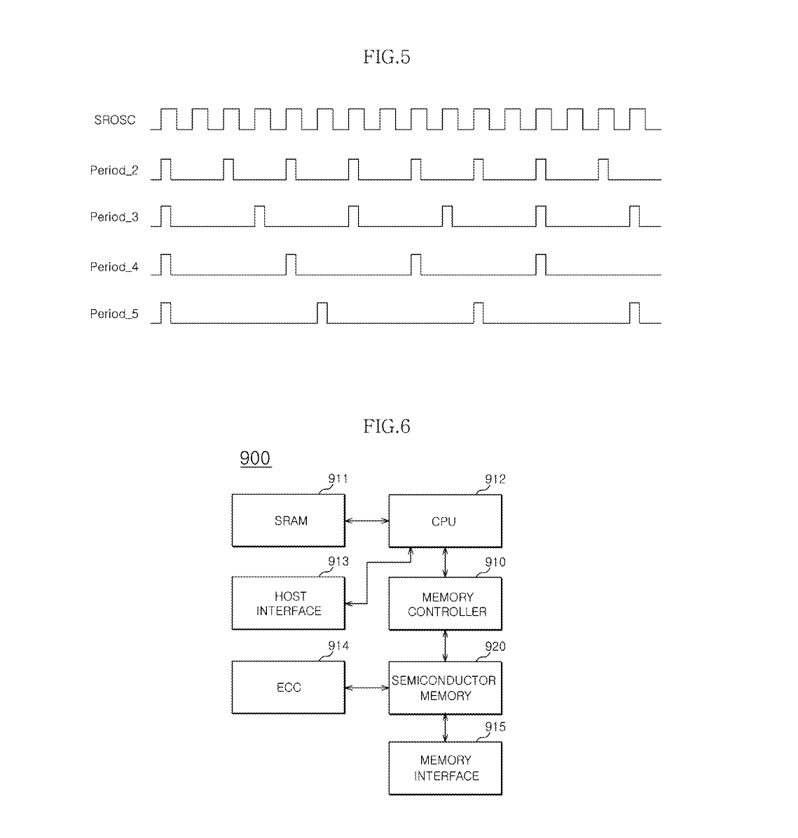

FIG. 6 is block diagram illustrating a memory system according to an embodiment of the present invention.

In FIG. 6, the memory system 900 of the present embodiment may include a semiconductor memory 920, a memory controller 910, and a CPU 912.

The semiconductor memory 920 may serve as a volatile memory device such as a DRAM. The memory controller 910 may control the semiconductor memory 920, and may include a static-random access memory (SRAM) 911, a host interface 913, an Error-Correction Code Block (ECC) 914, and a memory interface 915. The SRAM 911 may be used as an operation memory of the CPU 912. The CPU 912 may perform control operation for data exchange of the memory controller 910, and the host interface 913 may have data exchange protocol of a host accessed to the memory system 900. The ECC 914 may detect and correct error of data read from the semiconductor memory 920, and the memory interface 915 may interface with the semiconductor memory 920. The memory controller 910 may include further ROM for storing data for interfacing with the host, etc.

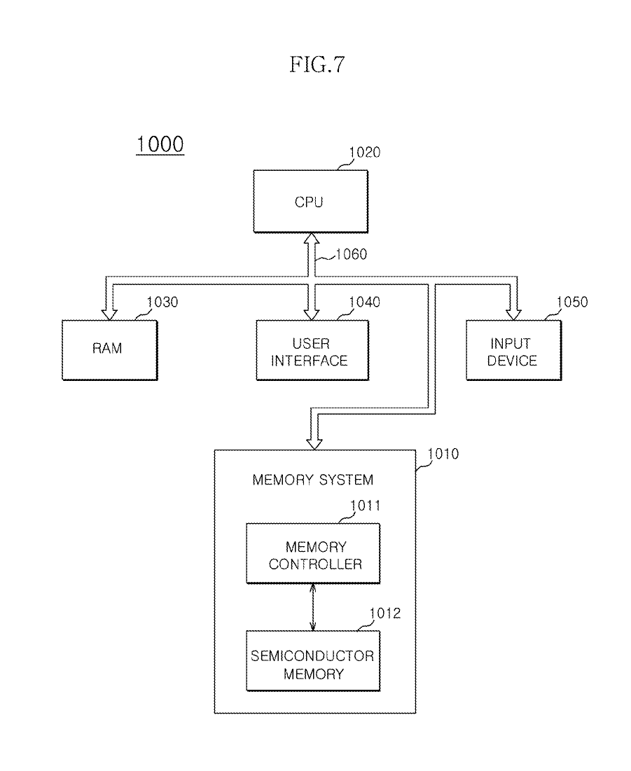

FIG. 7 is a view illustrating an electronic device or a computing system according to an embodiment of the present invention.

In FIG. 7, the computing system 1000 of the present embodiments may include a CPU 1020 connected to system bus 1060, a RAM 1030, a user interface 1040, an input device 1050, and a memory system 1010 including a memory controller 1011 and a semiconductor memory 1012. In case that the computing system 1000 is a mobile device, a battery (not shown) for supplying an operation voltage to the computing system 1000 may be further provided. The computing system 1000 of the present invention may further include an application chipset, a CMOS image processor CIS, a mobile DRAM, etc.

The user interface 1040 may be a self-contained display in the case of a portable electronic device. The input device 1050 may be a physical keyboard or a virtual keyboard in the case of a portable electronic device, and may further include, without limitation, a trackball, touchpad, or other cursor control device combined with a selection control, such as a pushbutton, to select an item highlighted by cursor manipulation. The memory system 1010 may include a semiconductor memory as described in FIG. 6.

Consequently, according to an embodiment of the present invention, current consumption due to unnecessary self-refresh and auto-refresh operations may decrease.

While certain embodiments have been described above, it will be understood to those skilled in the art that the embodiments described are by way of example only. Accordingly, the semiconductor memory system described herein should not be limited based on the described embodiments. Rather, the semiconductor memory system described herein should only be limited in light of the claims that follow when taken in conjunction with the above description and accompanying drawings.

What is claimed is:

1. A semiconductor memory system comprising:
a semiconductor memory configured to provide an external circuit with a plurality of refresh characteristic information and perform an auto-refresh operation in response to a plurality of auto-refresh commands; and
a memory controller configured to provide the semiconductor memory with the plurality of auto-refresh commands generated according to the plurality of refresh characteristic information.

2. The semiconductor memory system according to claim 1, wherein the semiconductor memory comprises:
a plurality of channels configured to provide the memory controller with the plurality of refresh characteristic information, perform the auto-refresh operation in response to the plurality of auto-refresh commands, and perform a self-refresh operation in response to a plurality of self-refresh period signals; and
a self-refresh period control unit configured to generate the plurality of self-refresh period signals having an independent period according to internal setting information.

3. The semiconductor memory system according to claim 2, wherein the plurality of refresh characteristic information is determined in a test process of the channels.

4. The semiconductor memory system according to claim 2, wherein each of the channels comprises:
a core block including a memory area and an input/output circuit; and
a peripheral circuit block configured to provide the memory controller with one of the plurality of refresh characteristic information, perform the auto-refresh operation in response to one of the plurality of auto-refresh commands, and perform the self-refresh operation in response to one of the plurality of self-refresh period signals.

5. The semiconductor memory system according to claim 2, wherein the self-refresh period control unit comprises:
an oscillator configured to generate an oscillation signal;
a preliminary period signal generation section configured to generate a plurality of preliminary period signals in response to the oscillation signal; and
a plurality of period signal generation sections configured to select one of the plurality of preliminary period signals according to the internal setting information and output the plurality of self-refresh period signals.

6. The semiconductor memory system according to claim 5, wherein each of the plurality of period signal generation sections comprises:
a fuse block configured to output a fuse signal as the internal setting information;
a decoding block configured to decode the fuse signal and generate a plurality of enable signals; and
a selection part configured to select one of the plurality of preliminary period signals in response to the plurality of enable signals and output one of the plurality of self-refresh period signals.

7. The semiconductor memory system according to claim 1, wherein the plurality of refresh characteristic information serves as the internal setting information.

8. The semiconductor memory system according to claim 1, wherein the memory controller is configured to independently set periods of the plurality of auto-refresh commands according to the plurality of refresh characteristic information.

9. A semiconductor memory system comprising:
a semiconductor memory configured to provide an external circuit with a plurality of refresh characteristic information according to refresh characteristics of respective channels, perform an auto-refresh operation for the respective channels in response to a plurality of auto-refresh commands, and stop a self-refresh operation of a channel corresponding to a plurality of self-refresh stop commands; and
a memory controller configured to provide the semiconductor memory with the plurality of auto-refresh commands and the plurality of self-refresh stop commands.

10. The semiconductor memory system according to claim 9, wherein the semiconductor memory comprises:
a plurality of channels configured to provide the memory controller with the plurality of refresh characteristic information, perform the auto-refresh operation in response to the plurality of auto-refresh commands, and perform a self-refresh operation in response to a plurality of self-refresh period signals; and
a self-refresh period control unit configured to generate the plurality of self-refresh period signals having an independent period according to internal setting information and selectively deactivate the plurality of self-refresh period signals in response to the plurality of self-refresh stop commands.

11. The semiconductor memory system according to claim 10, wherein the plurality of refresh characteristic information is determined in a test process of the channels.

12. The semiconductor memory system according to claim 10, wherein each of the channels comprises:
a core block including a memory area and an input/output circuit; and
a peripheral circuit block configured to provide the memory controller with one of the plurality of refresh characteristic information, perform the auto-refresh operation in response to one of the plurality of auto-refresh commands, and perform the self-refresh operation in response to one of the plurality of self-refresh period signals.

13. The semiconductor memory system according to claim 10, wherein the self-refresh period control unit comprises:
an oscillator configured to generate an oscillation signal;
a preliminary period signal generation section configured to generate a plurality of preliminary period signals in response to the oscillation signal; and
a plurality of period signal generation sections configured to select one of the plurality of preliminary period signals according to the internal setting information, output the plurality of self-refresh period signals, and deactivate the plurality of self-refresh period signals in response to the plurality of self-refresh stop commands.

14. The semiconductor memory system according to claim 13, wherein each of the plurality of period signal generation sections comprises:
a fuse block configured to output a fuse signal as the internal setting information;
a decoding block configured to decode the fuse signal and generate a plurality of enable signals; and
a selection part configured to select one of the plurality of preliminary period signals in response to the plurality of enable signals, output one of the plurality of self-refresh period signals, and deactivate one of the plurality of self-refresh period signals in response to one of the plurality of self-refresh stop commands.

15. The semiconductor memory system according to claim 9, wherein the plurality of refresh characteristic information serves as the internal setting information.

16. The semiconductor memory system according to claim 9, wherein the memory controller is configured to independently set periods of the plurality of auto-refresh commands according to the plurality of refresh characteristic information.

17. The semiconductor memory system according to claim 9, wherein the memory controller is configured to selectively activate the plurality of auto-refresh commands and the plurality of self-refresh stop commands according to the channel use information.

18. A semiconductor memory comprising:
a self-refresh period control unit configured to generate a plurality of self-refresh period signals each having an independent period according to internal setting information; and
a plurality of semiconductor memory cell regions configured to have different refresh characteristics from one another and each perform a self-refresh operation in response to one of the plurality of self-refresh period signals.

19. The semiconductor memory according to claim 18, wherein the self-refresh period control unit comprises:
an oscillator configured to generate an oscillation signal;
a preliminary period signal generation section configured to generate a plurality of preliminary period signals in response to the oscillation signal; and
a plurality of period signal generation sections configured to select one of the plurality of preliminary period signals according to the internal setting information and output the plurality of self-refresh period signals.

20. The semiconductor memory according to claim 19, wherein each of the plurality of period signal generation sections comprises:
a fuse block configured to output a fuse signal according to a fuse status;
a decoding block configured to decode the fuse signal and generate a plurality of enable signals; and
a selection part configured to select one of the plurality of preliminary period signals, output one of the plurality of self-refresh period signals, deactivate the one of the plurality of self-refresh period signals in response to a self-refresh stop command.

21. The semiconductor memory according to claim 18, wherein the self-refresh period control unit is configured to deactivate the plurality of self-refresh period signals in response to a plurality of self-refresh stop commands.

22. The semiconductor memory according to claim 18, further comprising:
a plurality of peripheral circuit blocks configured to provide the internal setting information.

23. A memory system comprising:
a memory controller configured to generate a plurality of auto refresh commands according to a plurality of refresh characteristic information; and
a semiconductor memory configured to provide an external circuit with the plurality of refresh characteristic information according to refresh characteristics of respective channels and perform an auto-refresh operation for the respective channels in response to the plurality of auto-refresh commands.

24. An electronic device comprising:
a semiconductor memory system communicatively coupled to a central processing unit; the semiconductor memory system comprising:
a memory controller configured to generate a plurality of auto refresh commands according to a plurality of refresh characteristic information; and
a semiconductor memory configured to provide an external circuit with the plurality of refresh characteristic information according to refresh characteristics of respective channels and perform an auto-refresh operation for the respective channels in response to the plurality of auto-refresh commands.
